(19) United States
(12) Patent Application Publication
(10) Pub. No.: US 2026/0235646 A1
(43) Pub. Date: Aug. 13, 2026

(54) PROBE STRUCTURE AND INSPECTION APPARATUS

(71) Applicant: KABUSHIKI KAISHA NIHON MICRONICS, Tokyo (JP)

(72) Inventors: Satoshi NARITA, Tokyo (JP); Takashi OGASAWARA, Tokyo (JP)

(21) Appl. No.: 19/377,299

(22) Filed: Nov. 3, 2025

(30) Foreign Application Priority Data
Nov. 5, 2024 (JP) 2024-193953

(51) Int. Cl. G01R 1/067

(52) U.S. Cl. CPC G01R 1/06772

(57) ABSTRACT

To make it possible to obtain matching of characteristic impedance at a connection terminal as a signal circuit relay point. The present disclosure provides a probe structure configured to transmit/receive a high-frequency signal to/from a device under test via a contact portion in electrical contact with an electrode of the device under test, the probe structure comprising: a main body part; a substrate holding member including a wiring substrate on one surface and fixed to the main body part on the other surface; a connector bonded to the wiring substrate of the substrate holding member and connecting wiring of the wiring substrate and a coaxial cable via a connection terminal; and an impedance adjustment unit configured to adjust a gap with the connection terminal to match an impedance.

### CROSS-REFERENCE TO RELATED APPLICATIONS

The present application claims priority under 35 U.S.C. 119 to Japanese Patent Application No. 2024-193953 filed on Nov. 5, 2024. The contents of this application are incorporated herein by reference in their entirety.

### TECHNICAL FIELD

The present disclosure relates to a probe structure and an inspection apparatus and can be applied to a probe structure and an inspection apparatus which are used to test electrical characteristics of high-frequency devices, such as semiconductor integrated circuits, for example.

### BACKGROUND ART

For example, when testing the electrical characteristics of a semiconductor integrated circuit on a semiconductor wafer, a prober apparatus is used to align probes. In particular, in order to test the electrical characteristics of high-frequency devices, high-frequency probes are used to transmit/receive high-frequency signals to/from the high-frequency devices.

FIG. 2 is a configuration diagram of a probe structure used to test a conventional high-frequency device under test.

In FIG. 2, a conventional probe structure 90 includes a lower ground plate 91, a probe substrate 92, an attaching unit 93, a coaxial connector 95, and an upper ground plate 99. The probe structure 90 is assembled by screwing screws 96 into attaching through-holes 93a and screw holes 91a. When a coaxial cable connected to the coaxial connector 95 comes into contact with a contact pad (also referred to as an “input/output signal terminal”) 951, an electrical connection is established.

### CITATION LIST

### Patent Literature

Patent Literature 1: Japanese Patent Application Laid-Open Publication No. 2006-194765

### SUMMARY OF INVENTION

### Technical Problem

However, when a member connected to ground (GND) is present near the input/output signal terminal, characteristic impedance of the input/output signal terminal may be reduced, which may affect high frequency measurements.

Accordingly, in view of the above-described problems, the present disclosure aims to provide a probe structure and inspection apparatus capable of obtaining matching of a characteristic impedance at a connection terminal as a signal circuit relay point.

### Solution to Problem

In order to solve this problem, a first aspect of the present disclosure provides a probe structure configured to transmit/receive a high-frequency signal to/from a device under test via a contact portion in electrical contact with an electrode of the device under test, the probe structure comprising: a main body part; a substrate holding member including a wiring substrate on one surface and fixed to the main body part on the other surface; a connector bonded to the wiring substrate of the substrate holding member and connecting wiring of the wiring substrate and a coaxial cable via a connection terminal; and an impedance adjustment unit configured to adjust a gap with the connection terminal to match an impedance.

A second aspect of the present disclosure provides an inspection apparatus configured to test electrical characteristics of a device under test using a high-frequency signal, the inspection apparatus comprising a probe structure, which is the probe structure according to the first aspect of the present disclosure, configured to transmit/receive the high-frequency signal to/from the device under test while electrically contacting a contact portion with an electrode of the device under test.

### Advantageous Effects of Invention

According to the present disclosure, it is possible to obtain matching of the characteristic impedance at the connection terminal as the signal circuit relay point.

### BRIEF DESCRIPTION OF DRAWINGS

FIG. 1 is a configuration diagram illustrating an external appearance configuration of a probe structure according to an embodiment.

FIG. 2 is a configuration diagram of a probe structure mounted on a conventional high-frequency prober apparatus.

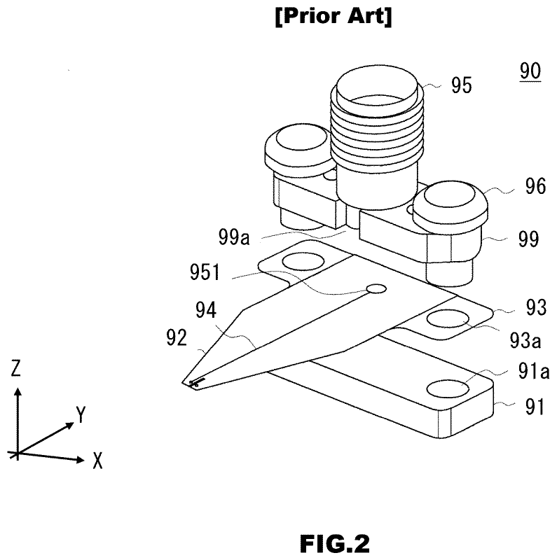

FIG. 3 is an explanatory diagram explaining a connection structure of the conventional probe structure.

FIG. 4 is an overall configuration diagram illustrating an overall configuration of a semiconductor inspection apparatus according to the embodiment.

FIG. 5 is an explanatory diagram explaining a connecting configuration of the probe structure according to the embodiment.

FIGS. 6(A) and 6(B) are diagrams illustrating a transmission path equivalent circuit, and an impedance at a conventional input/output signal terminal.

FIG. 7 is a diagram illustrating the impedance at the input/output signal terminal before and after adjustment, according to the embodiment.

FIG. 8 is a diagram illustrating return loss waveforms before and after impedance adjustment in the embodiment.

### DESCRIPTION OF EMBODIMENTS

### (A) Embodiment

Hereinafter, embodiments of a probe structure and an inspection apparatus according to the present disclosure will be described in detail with reference to the drawings.

This embodiment illustrates a case where an example of an inspection apparatus according to the present disclosure is applied to a semiconductor inspection apparatus configured to test electrical characteristics of high-frequency devices on a semiconductor wafer.

Moreover, this embodiment illustrates a case where an example of a probe structure according to the present disclosure is applied to a high-frequency probe structure mounted on the semiconductor inspection apparatus.

It is to be noted that the probe structure and the inspection apparatus according to the present disclosure are not limited to the high-frequency probe structure and the semiconductor inspection apparatus according to the embodiment.

### (A-1) Configuration of Semiconductor Inspection Apparatus

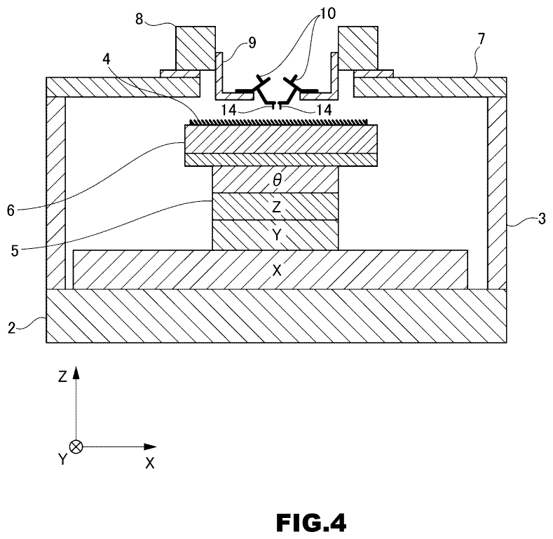

FIG. 4 is an overall configuration diagram illustrating an overall configuration of a semiconductor inspection apparatus according to the embodiment.

It is to be noted that each drawing illustrates the main components, but the present disclosure is not limited to the illustrated components and actually also include components that are not illustrated. In the description of each drawing, the identical or corresponding reference sign is attached to the identical or corresponding part. However, it should be noted that the drawings are schematic and the thickness and the size of each component part differs from an actual thing. Moreover, the part from which the mutual size and the ratio differ also in mutually drawings is included. The embodiments described hereinafter merely exemplify the device and method for materializing the technical idea according to the present disclosure; and the embodiments do not specify the material, shape, structure, arrangement, etc. of each component part according to the present disclosure.

In FIG. 4, the X direction, the Y direction, and the Z direction are defined. In FIG. 4, the X direction (first direction) is the right-left direction on the drawing sheet, the Y direction (second direction) is the depth direction on the drawing sheet, and the Z direction (third direction) is the up-down direction on the drawing sheet.

In FIG. 4, a semiconductor inspection apparatus 1 according to the embodiment includes a base portion 2, a frame portion 3, a device under test 4, a moving device 5, a mounting table 6, a top plate 7, a manipulator 8, a high-frequency probe structure attaching unit 9, and a high-frequency probe structure 10.

It is to be noted that, the semiconductor test device 1 is not limited to the configuration illustrated in FIG. 4, and may also be applied to, for example, a prober that does not include the base portion 2 and the frame portion 3, or a prober that uses a simple component instead of the base portion 2 and the frame portion 3. It may also include a microscope, a laser cutter device, etc.

The semiconductor inspection apparatus 1 uses a high-frequency device (semiconductor integrated circuit) formed on a semiconductor wafer as the device under test 4 and tests the electrical characteristics of the device under test 4 while electrically contacting contact portions (also referred to as “contactors” or “contact pins”) 14 with electrode terminals of the device under test 4. The semiconductor inspection apparatus 1 is also referred to as a prober.

During the test, the contact portion 14 of the high-frequency probe structure 10 is electrically contacted with the electrode terminal of the device under test 4, and the semiconductor inspection apparatus 1 supplies a high-frequency signal to the device under test 4 via the contact portion 14 and acquires a signal in response from the device under test 4 via the contact portion 14. In this manner, the electrical characteristics of the high-frequency device are tested. For example, the semiconductor inspection apparatus 1 tests the electrical characteristics of the high-frequency device using the high-frequency signal from a coaxial cable.

The mounting table 6 is configured to mount the device under test 4, such as a semiconductor chip or wafer. The mounting table 6 may include a temperature adjustment function of adjusting temperature of the device under test 4 to a high or low temperature.

The moving device 5 is configured to move the mounting table 6 on which the device under test 4 is mounted and to position the electrode terminal of the device under test 4 and the contact portion 14. For example, the moving device 5 includes an X-axis moving unit configured to move the mounting table 6 in the X-axis direction, a Y-axis moving unit configured to move the mounting table in the Y-axis direction, and a Z-axis moving unit configured to move the mounting table in the Z-axis direction, and a θ-axis moving unit configured to rotate the mounting table in the θ-axis direction, thereby enabling movement in the X, Y, Z, and θ axes. It is to be noted that, the moving device 5 is not limited to a device that moves the mounting table in four axial directions.

The high-frequency probe structure 10 includes the contact portion 14 that is brought into electrical contact with the electrode of the device under test and is configured to transmit/receive the high-frequency signal to/from the devices under test 4 via the contact portion 14. This example illustrates a case where two high-frequency probe structures 10 are provided.

The high-frequency probe structure 10 is attached to the high-frequency probe structure attaching unit 9 of the manipulator 8 and is connected to the coaxial cable, and the manipulator 8 is operated to align the contact portion 14 with the electrode of the device under test.

The manipulator 8 is provided on the top plate 7 and is configured to align the high-frequency probe structure 10. The manipulator 8 may be a manual type to be operated by an operator or may be an automatically controlled type.

### (A-2) High-Frequency Probe Structure

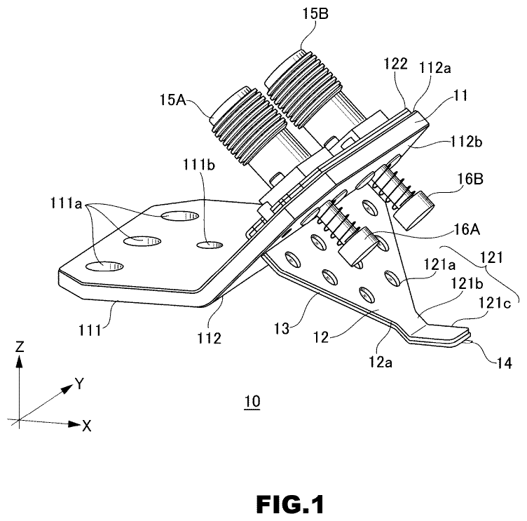

FIG. 1 is a configuration diagram illustrating an external appearance configuration of the high-frequency probe structure 10 according to the embodiment.

In FIG. 1, the high-frequency probe structure 10 according to the embodiment includes a body portion 11 as a main body part, an FPC (flexible printed circuit) holder 12 as a substrate holding member, an FPC 13 as a wiring substrate, a contact portion 14, connectors 15A and 15B, and impedance adjustment units 16A and 16B.

The body portion 11 is a main member used as a base of the high-frequency probe structure 10. The body portion 11 is a plate member formed, for example, of metal, such as iron, having a bend structure bent by a bending process. The body portion 11 having the bend structure includes a first plate portion 111 and a second plate portion 112.

The first plate portion 111 of the body portion 11 is a portion to be attached to the high-frequency probe structure attaching unit 9. The first plate portion 111 has three hole portions 111a, which are aligned, and one hole portion 111b, for attachment to the high-frequency probe structure attaching unit 9.

The second plate portion 112 of the body portion 11 is a portion configured to electrically connect coaxial cables connectable via the connectors 15A and 15B and a wiring pattern on the FPC 13 held by the FPC holder 12.

A long hole is provided on the second plate portion 112, and a first support portion (portion where the contact portion 14 is provided) 121 of the FPC holder 12 having bend structure is inserted into the long hole to be set. Consequently, the first support portion 121 of the FPC holder 12 having bend structure is inserted through the long hole of the body portion 11 to hold the FPC holder 12.

Furthermore, in the state where FPC holder 12 is inserted and set in the body portion 11, the first surface 112a of the second plate portion 112 and the second support portion 122 of the FPC holder 12 are overlapped with each other, and the connectors 15A and 15B are placed thereon to be fixed. Consequently, the FPC holder 12 can be sandwiched and fixed between the first surface 112a of the second plate portion 112 of the body portion 11 and the connectors 15A and 15B. Since the FPC holder 12 holds the FPC 13 made of a soft material, the connectors 15A and 15B are pressed against the FPC 13 to be bonded by contact pressure. It is to be noted that other fixing methods may also be applied.

The connectors 15A and 15B are connected to the coaxial cables.

The FPC 13 has a wiring pattern formed on a flexible substrate and is provided on the first surface 12a of the FPC holder 12. The wiring pattern on the FPC 13 is connected to the contact portion 14. As will be described later, when the connectors 15A and 15B are fixed, an input/output signal terminal 151 is connected to the wiring pattern on the FPC 13, and the coaxial cable and the wiring pattern on the FPC 13 can be connected to each other via the input/output signal terminal 151.

The FPC holder 12 is configured to hold the FPC 13 and is a plate member formed of a material, such as stainless steel. The FPC holder 12 has a bend structure which is bent at a substantially right angle by a bending process. The FPC 13 is bonded to the first surface 12a of the FPC holder 12 to hold the FPC 13 and to support the contact portion 14.

The FPC holder 12 having bend structure includes the first support portion 121 and the second support portion 122.

The first support portion 121 of the FPC holder 12 is a member on a side having a tip portion for supporting the contact portion 14. The first support portion 121 includes an approximately triangular base portion 121a of which a width (length in the Y-axis direction) decreases as it moves from the body portion 11 side to the tip side, an alignment portion 121c, which is a tip portion of the base portion 121a, configured to align the contact portion 14, and an elongated portion 121b between the base portion 121a and the alignment portion 121c.

The reason why the base portion 121a has the substantially triangular shape is to make it easier to align the contact portion 14 with the electrode terminal of the device under test 4. Similarly, the reason why the shape of the alignment portion 121c is rectangular (approximately oblong) as illustrated in FIG. 1 is that, although the test is usually performed using two high-frequency probe structures 10, the rectangular end portions of the pair of alignment portions 121c facing each other serves as a guide for alignment, making it easier to align the contact portion 14.

The second support portion 122 of the FPC holder 12 is a member on a side to be fixed to the body portion 11. The second support portion 122 is a member on the side to be fixed to the body portion 11 to support the first support portion 121 and to connect the input/output signal terminals 151 of the connectors 15A and 15B to the FPC 13.

The impedance adjustment units 16A and 16B are configured to adjust the decrease in impedance that occurs near the input/output signal terminals 151 as connection terminals.

The detailed configuration of the impedance adjustment units 16A and 16B will be described later, but is to adjust a distance between the input/output signal terminal 151 and the impedance adjustment unit 16 to perform impedance matching, for example. The impedance adjustment units 16A and 16B have a rod-shaped member (e.g., a screw) having an end surface at the tip and is configured to adjust the distance between this rod-shaped member and the input/output signal terminal 151. Moreover, the impedance adjustment units 16A and 16B are connected to the ground (GND).

For example, an adjustment hole 20 for adjusting impedance is formed in the FPC holder 12. Moreover, a through-hole 115 into which the impedance adjustment unit 16A, 16B as a screw is inserted is formed in the body portion 11. It is possible to obtain impedance matching by adjusting the distance between the impedance adjustment unit 16A, 16B inserted into the through-hole 115 and the input/output signal terminal 151.

It is to be noted that the impedance adjustment units 16A and 16B are respectively provided for the connectors 15A and 15B.

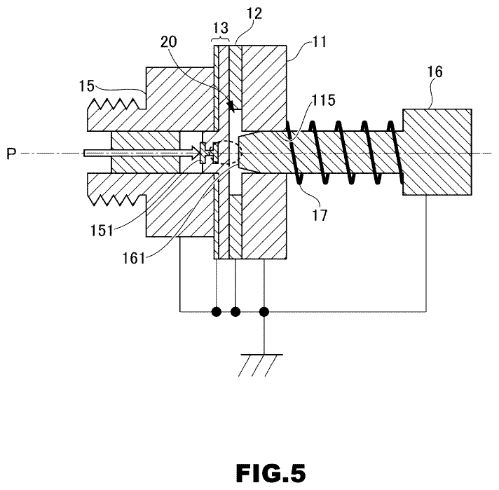

FIG. 5 is an explanatory diagram explaining a connecting configuration of the high-frequency probe structure 10 according to the embodiment.

The connection configurations of the connectors 15A and 15B are basically the same. Here, in order to describe the common configuration of the connectors 15A and 15B, the connectors 15A, 15B and the impedance adjustment units 16A, 16B will be respectively referred to as “connector 15” and “impedance adjustment unit 16”.

The FPC holder 12, the body portion 11, and the connector 15 are electrically connected to the ground. Moreover, the impedance adjustment unit 16 is electrically connected to the ground via the body portion 11.

In FIG. 5, the through-hole 115 is formed in the body portion 11, and the impedance adjustment unit 16 is inserted into the through-hole 115 of the body portion 11. The impedance adjustment unit 16 can be pushed and pulled in the through-hole 115.

Moreover, the impedance adjustment unit 16 may include a biasing member 17, such as a coil spring, to prevent loosening. When pushed into the body portion 11 side, the impedance adjustment unit 16 is biased and can move toward the body portion 11 side.

In the FPC holder 12, an adjustment hole 20 is formed at a position corresponding to the through-hole 115 of the body portion 11. Consequently, the tip portion 161 of the impedance adjustment unit 16 inserted into the through-hole 115 of the body portion 11 can reach the adjustment hole 20. Here, the tip of an impedance adjustment unit 16 disclosed herein is cut off to form a flat cross section. That is, the tip portion 161 is a cut surface. This makes it easier to adjust the size of the space in the adjustment hole 20.

The adjustment hole 20 passes through the FPC holder 12 but does not pass through the FPC 13. Accordingly, the adjustment hole 20 is a space surrounded by the FPC 13, the body portion 11, the wall surface of the FPC holder 12, and the tip portion 161 of the impedance adjustment unit 16, the size of the space of the adjustment hole 20 can be changed depending on the position of the impedance adjustment unit 16, which can be pushed and pulled. The impedance can be adjusted by changing the size of the space of the adjustment hole 20.

Here, a decrease in the characteristic impedance at the input/output signal terminal 151 of the high-frequency probe structure 10 will be described.

In the high-frequency probe structure 10, the contact portion 14 is connected to the input/output signal terminal 151 for high-frequency signals, and at this time, a design is required so that the impedance (output impedance) of the high-frequency circuit is equal to the impedance (input impedance) of the contact portion 14.

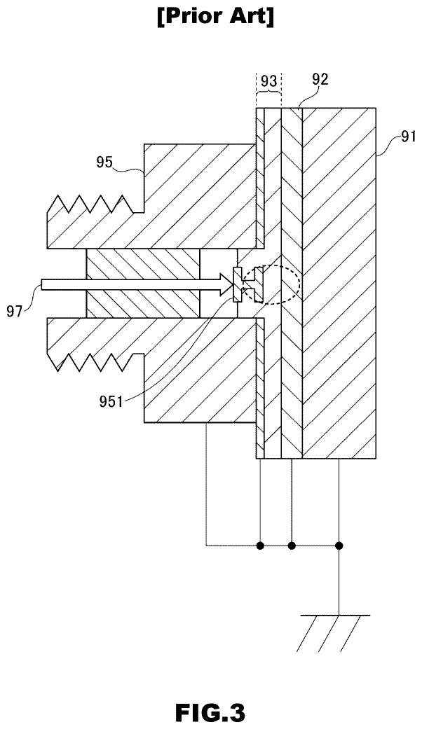

Conventionally, as illustrated in FIG. 3, the FPC holder and the body portion (corresponding to the probe substrate 92 and the lower ground plate 91 in FIG. 3) electrically connected to the ground are present opposite to the input/output signal terminal 951. Accordingly, the characteristic impedance at the input/output signal terminal 951 drops, affecting high frequency measurement.

For example, in order to prevent an occurrence of standing waves due to reflections serving as a hindrance of transmission of high-frequency signals, it is designed so that the impedance values (e.g., 50Ω) of input output impedances are matched. The characteristic impedance Z0 in the high-frequency probe configured to transmit a high-frequency signal is expressed by the following equation (1).

$$\begin{matrix}[ Equation 1 ] & \\ Z 0 = \sqrt{\{ ( R + j 2 π {f}_{C} L ) / ( G + j 2 π f C ) \}} \approx \sqrt{L / C} & ( 1 )\end{matrix}$$

In the equation (1), C is capacitance (electrostatic capacitance) and L is inductance. The characteristic impedance Z0 is directly proportional to L and inversely proportional to C.

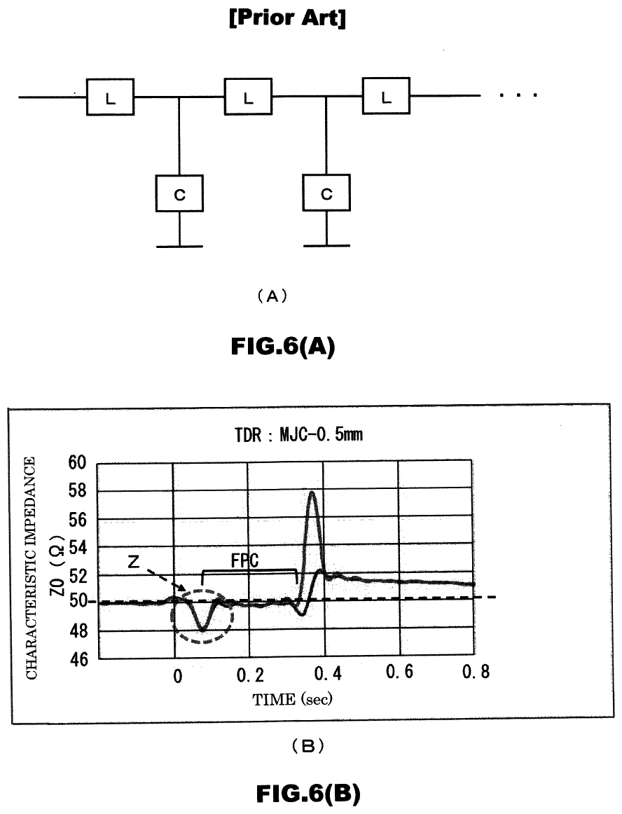

FIG. 6(A) illustrates a transmission path equivalent circuit. In the input/output signal terminal 951, since the FPC holder and the body portion (corresponding to the probe substrate 92 and the lower ground plate 91 illustrated in FIG. 3) are present near the input/output signal terminal 951, the capacitance C is large, and therefore the characteristic impedance Z0 is small (refer to the portion Z in FIG. 6(B)).

In view of the above-described problem of the conventional technology, this embodiment is configured so that the adjustment hole 20 is formed in the FPC holder 12 to increase the distance between the input/output signal terminal 151 and the FPC holder 12 and body portion 11, as illustrated in FIG. 5. Furthermore, the impedance adjustment unit 16 is provided to change the size of the space of the adjustment hole 20. In other words, the gap between the input/output signal terminal 151 and the impedance adjustment unit 16 is changed. Consequently, the capacitance C can be reduced and the value of the characteristic impedance Z0 can be adjusted.

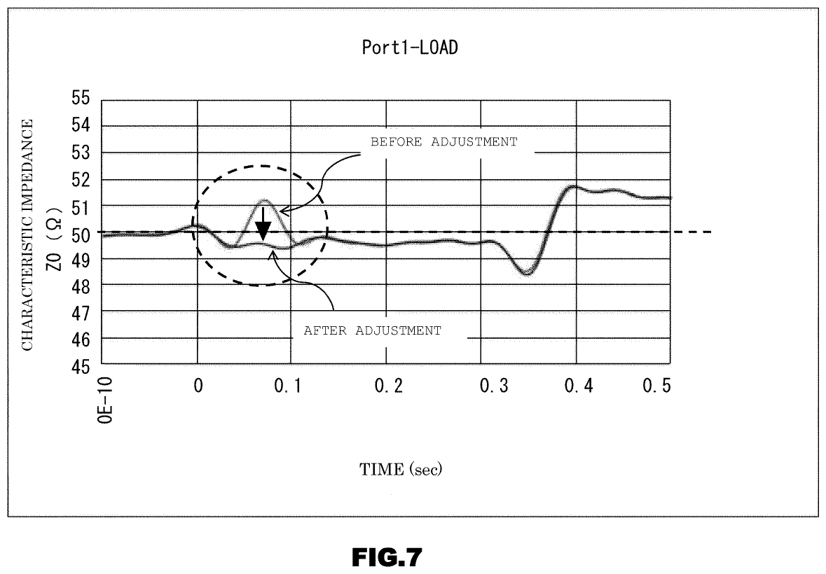

FIG. 7 is a diagram illustrating an impedance at the input/output signal terminal 151 before and after adjustment by the impedance adjustment unit 16 according to the embodiment.

Before the adjustment, in a state where the impedance adjustment unit 16 is not set, the adjustment hole 20 is formed in the FPC holder 12 and the through-hole 115 is formed in the body portion 11 by tap processing so that the value of the capacitance C is low. The central axis of the through-hole 115 and the central axis of the input/output signal terminal 151 are coaxially arranged (P axis in FIG. 5). In this case, as illustrated in FIG. 7, the value of the impedance Z0 is increased.

Thereafter, the impedance adjustment unit 16 can obtain a GND signal from the through-hole 115 of the body portion 11 and adjusts the value of the impedance 20 by pushing and pulling the impedance adjustment unit 16 as a screw.

For example, when the impedance adjustment unit 16 is pushed into the through-hole 115 and the distance between the input/output signal terminal 151 and the impedance adjustment unit 16 is reduced, the value of the capacitance C is increased, and the input/output impedance can be designed to the impedance value (e.g., 50Ω) as illustrated in FIG. 7.

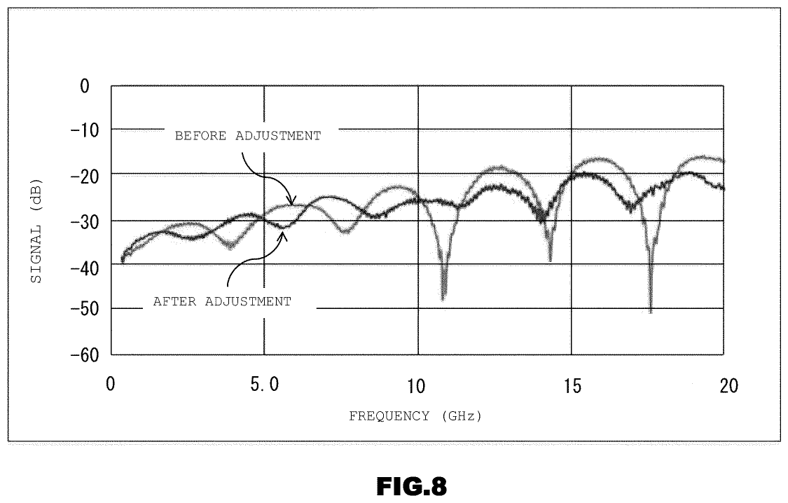

FIG. 8 is a diagram illustrating return loss waveforms before and after impedance adjustment in the embodiment.

When handling high-frequency signals, all impedances are designed to match in order to reduce reflection. For example, even when the input and output impedance values are designed to be equal to 50Ω, if there is a point along the signal path where the impedance changes, a reflection phenomenon occurs in which part of the signal does not proceed to the receiving side but returns to the transmitting side.

From the results in FIG. 8, it can be seen that, on the basis of the return loss before and after adjustment, the reflection can be reduced after adjustment compared to before adjustment, and the characteristics can be improved.

### (A-3) Advantageous Effects of Embodiment

As described above, according to the present embodiment, the impedance adjustment unit, which can be pushed and pulled through the through-hole in the body portion, adjusts the gap with the input/output signal terminal, thereby obtaining matching of the characteristic impedance at the connection terminal as a signal circuit relay point.

### (B) Other Embodiments

Although various modified embodiments have been described in the above-described embodiment, the present disclosure can also be applied to the following modified embodiments.

(B-1) In the above-described embodiment, the high-frequency probe structure includes two connectors, but it can also be applied to a case of including one connector or three or more connectors. Even in such cases, the connection structure in each connector is the same as that described in the above embodiment, and similar effects can be obtained.
(B-2) Generally, impedance matching in an electrical circuit using a high-frequency signal requires highly accurate control of the connection structure, but the present embodiment is configured so that a rod-like member such as an adjustment screw can be pushed and pulled, making it possible to control the impedance even with a simple structure. It is desirable that the central axis of the input/output signal terminal and the axis of the impedance adjustment unit are the same axis, but the impedance can be adjusted without completely matching both axes.

Reference Signs List

1: Semiconductor inspection apparatus; 2: Base portion; 3:
Frame portion; 4: Device under test; 5: Moving device;
6: Mounting table; 7: Top plate; 8: Manipulator; 9: Probe
structure attaching unit;
10: High-frequency probe structure; 11: Body portion; 111:
First plate portion of body portion; 111a and 111b: Hole portion;
112: Second plate portion of body portion; 112a: First surface
of second plate portion of body portion; 115: Through-hole;
12: FPC holder; 12a: First surface of FPC holder; 121:
First support portion of FPC holder; 121b: Base portion of FPC
holder; 121c: Alignment portion of FPC holder; 122: Second
support portion of FPC holder;
13: FPC; 14: Contact portion;
15 (15A and 15B): Connector; 151: Input/output signal terminal;
16 (16A and 16B): Impedance adjustment unit; 161: Tip
portion of impedance adjustment unit; 17: Biasing member; 20:
Adjustment hole;
90: Probe structure; 91: Body portion; 92: FPC holder; 93:
FPC; 94: Contact portion; and 951: Input/output signal terminal.

1. A probe structure configured to transmit/receive a high-frequency signal to/from a device under test via a contact portion, the contact portion being in electrical contact with an electrode of the device under test, the probe structure comprising:
a main body part;
a substrate holding member including a wiring substrate on one surface, the substrate holding member fixed to the main body part on the other surface;
a connector bonded to the wiring substrate of the substrate holding member, the connector connecting wiring of the wiring substrate and a coaxial cable via a connection terminal; and
an impedance adjustment unit configured to adjust a gap with the connection terminal to match an impedance.

2. The probe structure according to claim 1, wherein
the substrate holding member has a space formed around the connection terminal,
the main body part has a through-hole at a position corresponding to the space formed in the substrate holding member, and
the impedance adjustment unit has a rod-like member which can be pushed and pulled through the through-hole of the main body part and is configured to adjust a gap between the connection terminal and the rod-like member.

3. The probe structure according to claim 1, wherein the substrate holding member, the main body part, the connector, and the impedance adjustment unit are connected to a ground.

4. The probe structure according to claim 2, wherein a tip of the rod-like member of the impedance adjustment unit is an end surface.

5. The probe structure according to claim 1, wherein the wiring substrate of the substrate holding member is a flexible substrate.

6. An inspection apparatus configured to test electrical characteristics of a device under test using a high-frequency signal, the inspection apparatus comprising:
the probe structure according to claim 1, configured to transmit/receive the high-frequency signal to/from the device under test while electrically contacting a contact portion with an electrode of the device under test.

7. An inspection apparatus configured to test electrical characteristics of a device under test using a high-frequency signal, the inspection apparatus comprising:
the probe structure according to claim 2, configured to transmit/receive the high-frequency signal to/from the device under test while electrically contacting a contact portion with an electrode of the device under test.

8. An inspection apparatus configured to test electrical characteristics of a device under test using a high-frequency signal, the inspection apparatus comprising:
the probe structure according to claim 3, configured to transmit/receive the high-frequency signal to/from the device under test while electrically contacting a contact portion with an electrode of the device under test.

9. An inspection apparatus configured to test electrical characteristics of a device under test using a high-frequency signal, the inspection apparatus comprising:
the probe structure according to claim 4, configured to transmit/receive the high-frequency signal to/from the device under test while electrically contacting a contact portion with an electrode of the device under test.

10. An inspection apparatus configured to test electrical characteristics of a device under test using a high-frequency signal, the inspection apparatus comprising:
the probe structure according to claim 5, configured to transmit/receive the high-frequency signal to/from the device under test while electrically contacting a contact portion with an electrode of the device under test.
